(19) United States
(12) Patent Application Publication
(10) Pub. No.: US 2021/0195794 A1
(43) Pub. Date: Jun. 24, 2021

(54) NOVEL MECHANICAL PUMP LIQUID-COOLING HEAT DISSIPATION SYSTEM

(71) Applicant: HUAZHONG UNIVERSITY OF SCIENCE AND TECHNOLOGY, Hubei (CN)

(72) Inventors: Xiaobing LUO, Hubei (CN); Falong LIU, Hubei (CN); Bin DUAN, Hubei (CN); Han WU, Hubei (CN); Jinyan HU, Hubei (CN); Ruikang WU, Hubei (CN); Xingjian YU, Hubei (CN)

(73) Assignee: HUAZHONG UNIVERSITY OF SCIENCE AND TECHNOLOGY, Hubei (CN)

(21) Appl. No.: 16/079,087

(22) PCT Filed: Apr. 24, 2017
(86) PCT No.: PCT/CN2017/081642

§ 371 Date: Aug. 22, 2018

(30) Foreign Application Priority Data
Mar. 31, 2017 (CN) 201710208116.8

(51) Int. Cl. H05K 7/20; F04D 29/42; F04D 29/44; F04D 29/02; F04D 29/58

(52) U.S. Cl. CPC H05K 7/20272; F04D 29/4293; F04D 29/5893; F04D 29/026; F04D 29/445

(57) ABSTRACT

The present invention belongs to the technical field of liquid-cooling heat dissipation, wherein discloses a novel mechanical pump liquid-cooling heat dissipation system, comprising an external radiator, a circulating pipe and a mechanical pump, wherein the circulating pipe communicates the external radiator with the circulating pipe to form a circulation loop, the mechanical pump includes a volute in the form of a hollow cylinder, a fixing surface is formed at one end of the volute, the fixing surface is planar and is part of the outer surface of the volute, a layer of heat-conducting silicone grease is coated on the fixing surface, the fixing surface and a heat source are fixed through pressure lamination, and the heat-conducting silicone grease is attached to the fixing surface and the heat source; and the mechanical pump takes away heat of the heat source and transfers it to a cooling working medium while pumping the cooling working medium to circulate in the circulation loop.

### BACKGROUND OF THE INVENTION

### Technical Field

The present invention belongs to the technical field of liquid-cooling heat dissipation, and more particularly relates to a novel mechanical pump liquid-cooling heat dissipation system.

### Description of the Related Art

With the rapid development of electronic technology, electronic equipment is rapidly developing in terms of function diversification, information, integration and the like. The heat flow of electronic equipment is continuously rising, and is approaching the limit of air-cooling heat dissipation (less than 100 W/m²), so that it is difficult for traditional air-cooling heat dissipation to meet heat dissipation requirements. Due to the advantages of high heat dissipation efficiency, large heat capacity of the cooling working medium, low cost and the like, liquid-cooling heat dissipation will be widely used.

At present, the liquid-cooling heat dissipation system consists of a cold plate, a circulating pipe, a pump and an external radiator. Under the action of the pump, the cooling working medium flows through the cold plate to take away the waste heat generated by the electronic components, the temperature of the cooling working medium rises, the cooling working medium dissipates heat when passing through the external radiator, and then the cooled liquid flows back to the cold plate, so that thermal control is achieved in such a circulating way. The liquid-cooling radiator has a simple and compact structure and a high heat transfer coefficient, and produces a significantly smaller noise than that of the air-cooling system during operation. The cold plate of the liquid-cooling system mostly uses serpentine or horizontal channels that are easy to process, and by increasing the flow rate of the liquid in the channels, the cooling liquid reaches a turbulent state to enhance heat transfer. However, there are also many drawbacks in meeting the heat dissipation requirement only by increasing the flow rate, for example, increasing the flow rate also brings about an increase in the fluid resistance and the power consumption of the pump. In order to find an efficient liquid-cooling technology, the microchannel heat dissipation technology is applied to the liquid-cooling technology, and the microchannels have a small volume and high heat dissipation efficiency, but also feature increased pressure drop and higher requirements on the pump as well as complex structure, complicated manufacturing process and high cost. Accordingly, there is a need in the art to develop a liquid-cooling heat dissipation system with a simple structure and good heat dissipation performance.

### SUMMARY OF THE PRESENT INVENTION

In view of the above-described problems, the present invention provides a novel mechanical pump liquid-cooling heat dissipation system, in which the rotation of vanes in the mechanical pump and the diffusing structure of the volute make the turbulent flow of the cooling working medium in the mechanical pump very complicated, creating a good liquid-cooling heat dissipation condition and eliminating the need of the cold plate structure. By improving the volute structure of the mechanical pump in such a way that the volute directly contacts the heat source so that the cooling working medium takes away the waste heat generated by the electronic device while passing through the mechanical pump, the cost is reduced, the structure is simplified, the heat dissipation performance of the liquid-cooling heat dissipation system is improved, the requirements on the pump are reduced, and the practicability and reliability of the liquid cooling system are improved.

In order to achieve the above objective, the present invention provides a novel mechanical pump liquid-cooling heat dissipation system, comprising an external radiator, a circulating pipe and a mechanical pump, the circulating pipe communicating the external radiator with the circulating pipe to form a circulation loop, characterized in that:

the mechanical pump includes a volute in the form of a hollow cylinder, a fixing surface is formed at one end of the volute, the fixing surface is planar and is a part of the outer surface of the volute, a layer of heat-conducting silicone grease is coated on the fixing surface, the fixing surface and a heat source are fixed together through pressure lamination, and the heat-conducting silicone grease is attached to both the fixing surface and the heat source;

an outlet connection and an inlet connection are formed on the circumferential surface of the volute to respectively communicate with the circulating pipe, and the mechanical pump takes away heat of the heat source and transfers the heat to a cooling working medium while pumping the cooling working medium to circulate in the circulation loop.

Further, the volute is further formed with a receiving chamber, the receiving chamber penetrating the other end of the volute and communicating with the outlet connection and the inlet connection.

Further, the receiving cavity is stepped, and its central axis is perpendicular to the fixing surface; and a water passage is formed on the bottom surface of the receiving cavity to enable the flow of the cooling working medium.

Further, a plurality of spaced microchannels are formed on the water passage to enhance the turbulent flow of the cooling working medium in the volute.

Further, the plurality of microchannels are evenly arranged around the central axis of the volute.

Further, the volute is made of copper.

In general, by comparing the above technical solution of the present inventive concept with the prior art, the novel mechanical pump liquid-cooling heat dissipation system provided in the present invention has the following beneficial effects:

(1) the fixing surface is designed to be planar, and the heat resource is fixed on the fixing surface of the volute, which eliminates the need of the cold plate structure. The mechanical pump takes away heat of the heat source and transfers the heat to the cooling working medium while pumping the cooling working medium, so that the pressure drop caused by the cold plate structure is avoided, the structure is simplified, the cost is reduced, and the practicability and reliability of the liquid cooling system are improved;

(2) a layer of heat-conducting silicone grease is coated on the fixing surface, and the heat-conducting silicone grease is attached to both the fixing surface and the heat source, thereby enhancing the heat transfer between the heat source and the volute and improving the heat dissipation performance; and

(3) a plurality of spaced microchannels are formed on the water passage, thereby enhancing the turbulent flow of the cooling working medium in the volute and then improving the heat dissipation performance.

### BRIEF DESCRIPTION OF THE DRAWINGS

FIG. 1 is a schematic diagram of use state of a novel mechanical pump liquid-cooling heat dissipation system according to a preferred embodiment of the present invention.

FIG. 2 is a schematic diagram of a mechanical pump in the novel mechanical pump liquid-cooling heat dissipation system in FIG. 1.

FIG. 3 is a schematic diagram of a volute in the mechanical pump in FIG. 2.

FIG. 4 is a schematic diagram of a volute in the mechanical pump in the novel mechanical pump liquid-cooling heat dissipation system according to another embodiment of the present invention.

In all figures, the same elements or structures are denoted by the same reference numerals, in which: 1—external radiator, 2—circulating pipe, 3—volute, 31—fixing surface, 32—outlet connection, 33—inlet connection, 34—receiving chamber, 35—water passage, 36—microchannel, 4—heat source.

### DETAILED DESCRIPTION OF THE EMBODIMENTS

For clear understanding of the objectives, features and advantages of the present invention, detailed description of the present invention will be given below in conjunction with accompanying drawings and specific embodiments. It should be noted that the embodiments described herein are only meant to explain the present invention, and not to limit the scope of the present invention. Furthermore, the technical features related to the embodiments of the invention described below can be mutually combined if they are not found to be mutually exclusive.

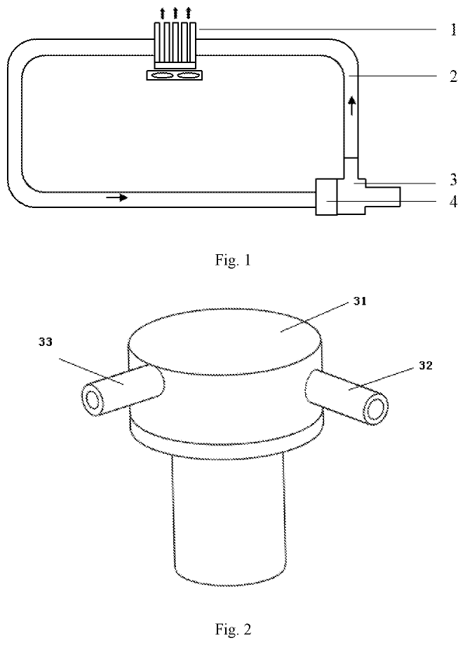

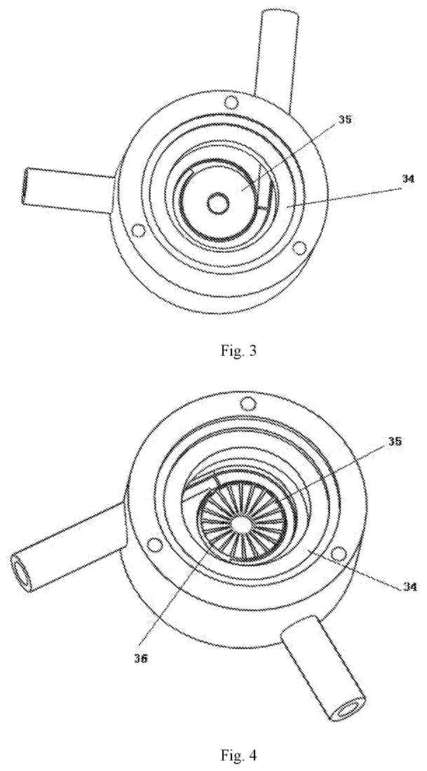

Referring to FIGS. 1-3, in the novel mechanical pump liquid-cooling heat dissipation system according to a preferred embodiment of the present invention, the volute structure of the mechanical pump is changed such that the heat source directly contacts the volute, which eliminates the need of the cold plate structure in the liquid-cooling heat dissipation system. The cooling working medium takes away waste heat generated by the electronic device while being conveyed by the mechanical pump, the heat is dissipated when the cooling working medium passes through the external radiator, then the cooled cooling working medium flows back to the mechanical pump, so that thermal control is achieved in such a circulating way. The novel mechanical pump liquid-cooling heat dissipation system utilizes the complicated turbulent flow inside the mechanical pump to dissipate the heat of the heat source, thereby achieving the effects of simplifying the structure, reducing the pressure drop, and improving the heat dissipation performance.

The novel mechanical pump liquid-cooling heat dissipation system includes an external radiator 1, a mechanical pump and a circulating pipe 2, in which the circulating pipe 2 communicates the external radiator 1 with the mechanical pump to form a circulation loop, and the cooling working medium circularly flows in the circulating pipe 2, the external radiator 1 and the mechanical pump. The external radiator 1 is configured to dissipate the heat carried by the cooling working medium. The mechanical pump is connected to a heat source 4 to dissipate the heat of the heat source 4 and transfer the heat to the cooling working medium flowing through the mechanical pump. When the cooling working medium carrying the heat passes through the external radiator 1, the external radiator 1 dissipates the heat carried by the cooling working medium, and then, through the circulating pipe 2, the cooled cooling working medium flows back to the mechanical pump for circulation. The mechanical pump is also used to pump the cooling working medium so that the cooling working medium is circulated at a predetermined pressure and flow rate.

The mechanical pump includes a volute 3 and vanes housed in the volute 3. The rotation of the vanes and the diffusing structure of the volute 3 make the turbulent flow of the cooling working medium in the mechanical pump very complicated, creating a good liquid-cooling heat dissipation condition. Thus, the mechanical pump can be directly used for heat dissipation of electronic devices. In the present embodiment, the heat source 4 is an electronic device.

The volute 3 is substantially in the form of a hollow cylinder, one end of which is formed with a fixing surface (upper surface) 31 perpendicular to the central axis of the volute 3. In the present embodiment, the volute 3 is connected to the heat source 4 through the fixing surface 31 which is a part of the outer surface of the volute 3. The volute 3 is further provided with a stepped receiving chamber 34 which penetrates the other end of the volute 3. The stepped receiving chamber 34 is used for receiving the vanes. In the present embodiment, the central axis of the receiving chamber 34 coincides with the central axis of the volute 3.

A water passage 35 is formed on the bottom surface of the receiving cavity 34 to enable the flow of the cooling working medium so as to take away heat transferred from the heat source 4 in the volute 3. An outlet connection 32 and an inlet connection 33 are further formed on the circumferential surface (side surface) of the volute 3, the outlet connection 32 and the inlet connection 33 being spaced apart from each other and communicating with the receiving cavity 34. The outlet connection 32 and the inlet connection 33 respectively communicate with the circulating pipe 2 to allow the cooling working medium to flow between the circulating pipe 2 and the mechanical pump.

In the present embodiment, the volute 3 is made of copper so as to improve the heat transfer between the heat source 4 and the volute 3; and a layer of heat-conducting silicone grease is coated on the fixing surface 31, the heat source 4 and the fixing surface 31 are fixed through pressure lamination, and the heat-conducting silicone grease is attached to both the fixing surface 31 and the heat source 4 so that the mechanical pump can directly take away the heat of the heat source 4.

When the novel mechanical pump liquid-cooling heat dissipation system is in operation, the heat source 4 is fixed on the fixing surface 31 of the volute 3, the mechanical pump pumps the cooling working medium to circularly flow in the circulating pipe 2, the external radiator 1 and the mechanical pump, and meanwhile the volute 3 of the mechanical pump directly dissipates the heat of the heat source 4 and then transfers the heat of the heat source 4 to the cooling working medium; when the cooling working medium carrying the heat flows through the external radiator 1, the external radiator 1 dissipates the heat carried by the cooling working medium, and under the action of the mechanical pump, the cooled cooling working medium flows back to the volute 3 of the mechanical pump through the circulating pipe 2 for circulation.

It can be understood that, in another embodiment, a plurality of spaced microchannels 36 may be formed on the water passage 35 to enhance the turbulent flow of the cooling working medium in the volute 3 so as to improve the heat dissipation performance; and the plurality of microchannels 36 are evenly arranged around the central axis of the volute 3, as shown in FIG. 4.

In the novel mechanical pump liquid-cooling heat dissipation system, the rotation of the vanes in the mechanical pump and the diffusing structure of the volute make the turbulent flow of the cooling working medium in the mechanical pump very complicated, creating a good liquid-cooling heat dissipation condition and eliminating the need of the cold plate structure. By improving the volute structure of the mechanical pump in such a way that the volute directly contacts the heat source so that the cooling working medium takes away the waste heat generated by the electronic device while passing through the mechanical pump, the cost is reduced, the structure is simplified, the heat dissipation performance of the liquid-cooling heat dissipation system is improved, the requirements on the pump are reduced, and the practicability and reliability of the liquid cooling system are improved.

It should be readily understood to those skilled in the art that the above description is only preferred embodiments of the present invention, and do not limit the scope of the present invention. Any changes, equivalent substitution and modifications made without departing from the spirit and scope of the present invention should be included within the scope of the protection of the present invention.

1. A mechanical pump liquid-cooling heat dissipation system, comprising an external radiator, a circulating pipe and a mechanical pump, the circulating pipe communicating the external radiator with the circulating pipe to form a circulation loop wherein,
the mechanical pump includes a volute in the form of a hollow cylinder, a fixing surface is formed at one end of the volute, the fixing surface is planar and is a part of the outer surface of the volute, a layer of heat-conducting silicone grease is coated on the fixing surface, the fixing surface and a heat source are fixed together through pressure lamination, and the heat-conducting silicone grease is attached to both the fixing surface and the heat source; and
an outlet connection and an inlet connection are formed on the circumferential surface of the volute to respectively communicate with the circulating pipe, and the mechanical pump takes away heat of the heat source and transfers the heat to a cooling working medium while pumping the cooling working medium to circulate in the circulation loop.

2. The mechanical pump liquid-cooling heat dissipation system of claim 1, wherein the volute is further formed with a receiving chamber, the receiving chamber penetrating the other end of the volute and communicating with the outlet connection and the inlet connection.

3. The mechanical pump liquid-cooling heat dissipation system of claim 1, wherein the receiving cavity is stepped, and its central axis is perpendicular to the fixing surface; and a water passage is formed on the bottom surface of the receiving cavity to enable the flow of the cooling working medium.

4. The mechanical pump liquid-cooling heat dissipation system of claim 3, wherein a plurality of spaced microchannels are formed on the water passage to enhance the turbulent flow of the cooling working medium in the volute.

5. The mechanical pump liquid-cooling heat dissipation system of claim 4, wherein the plurality of microchannels are evenly arranged around the central axis of the volute.

6. The mechanical pump liquid-cooling heat dissipation system of claim 1, wherein the volute is made of copper.

7. The mechanical pump liquid-cooling heat dissipation system of claim 2, wherein the receiving cavity is stepped, and its central axis is perpendicular to the fixing surface; and a water passage is formed on the bottom surface of the receiving cavity to enable the flow of the cooling working medium.

8. The mechanical pump liquid-cooling heat dissipation system of claim 2, wherein the volute is made of copper.
